(19) United States
(12) Patent Application Publication
(10) Pub. No.: US 2026/0214881 A1
(43) Pub. Date: Jul. 23, 2026

(54) Memory Circuitry And Methods Used In Forming Memory Circuitry

(71) Applicant: Micron Technology, Inc., Boise, ID (US)

(72) Inventors: Yuanzhi Ma, Meridian, ID (US); Ruijing Ge, Boise, ID (US); Sandeep Krishna Thirumala, Meridian, ID (US)

(73) Assignee: Micron Technology, Inc., Boise, ID (US)

(21) Appl. No.: 19/072,039

(22) Filed: Mar. 6, 2025

Related U.S. Application Data
(60) Provisional application No. 63/747,141, filed on Jan. 20, 2025.

(51) Int. Cl. H10B 12/00

(52) U.S. Cl. CPC H10B 12/30; H10B 12/02

(57) ABSTRACT

Memory circuitry comprises vertically-alternating insulative tiers and memory-cell tiers. Memory cells in the memory-cell tiers individually comprise a horizontal transistor having a gate, a capacitor side, and a digitline side. A capacitor is electrically coupled with the horizontal transistor on the capacitor side. A digitline is electrically coupled with the horizontal transistor on the digitline side. The insulative tiers comprise insulative material that is vertically between immediately-vertically-adjacent of the memory-cell tiers. A portion of the insulative material is laterally beyond a digitline-side edge of the gates of the immediately-vertically-adjacent memory cells. The portion tapers towards the digitline. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-13 are diagrammatic sectional views of constructions in accordance with embodiments of the invention.

FIGS. 14-21 are diagrammatic sequential sectional and/or enlarged views of the construction of FIGS. 3-13, or portions thereof or alternate and/or additional embodiments, in process in accordance with some embodiments of the invention.

### DETAILED DESCRIPTION OF EXAMPLE EMBODIMENTS

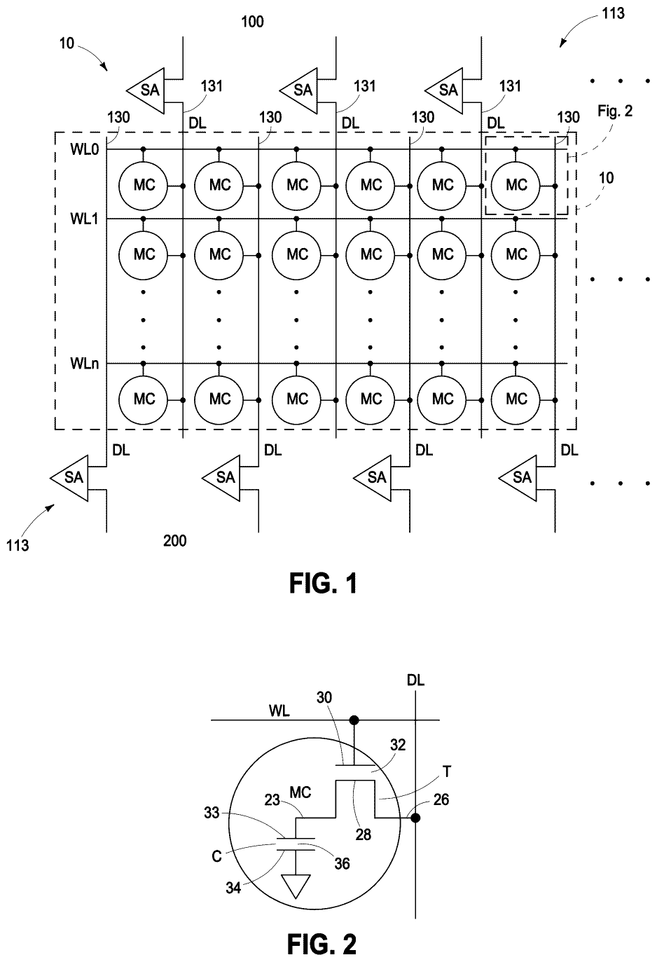

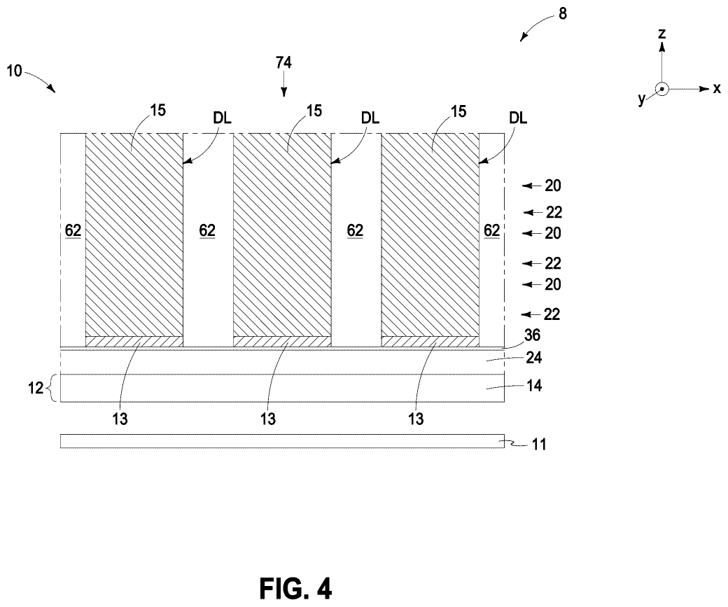

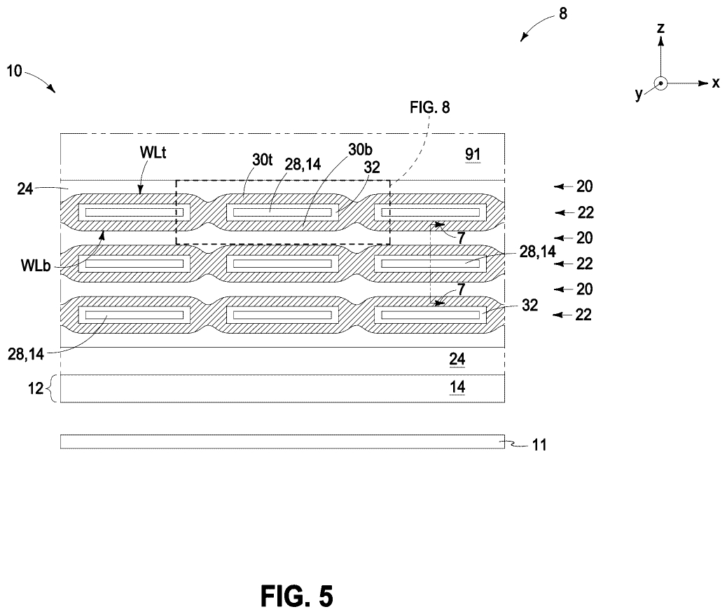

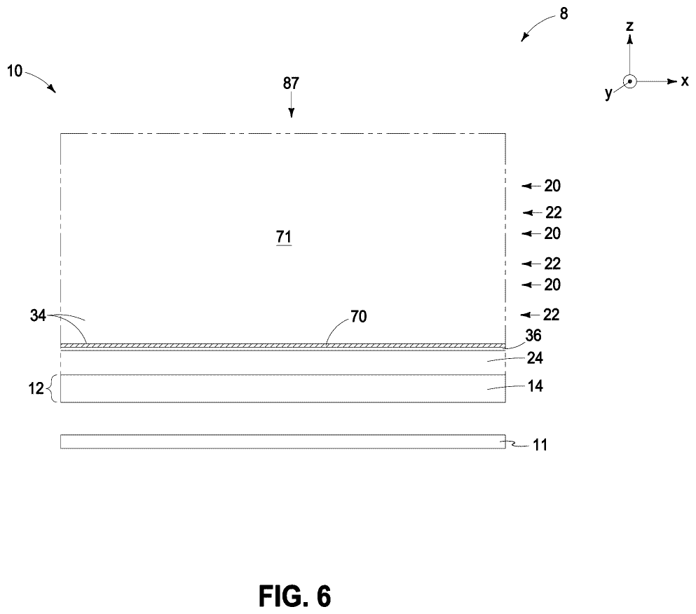

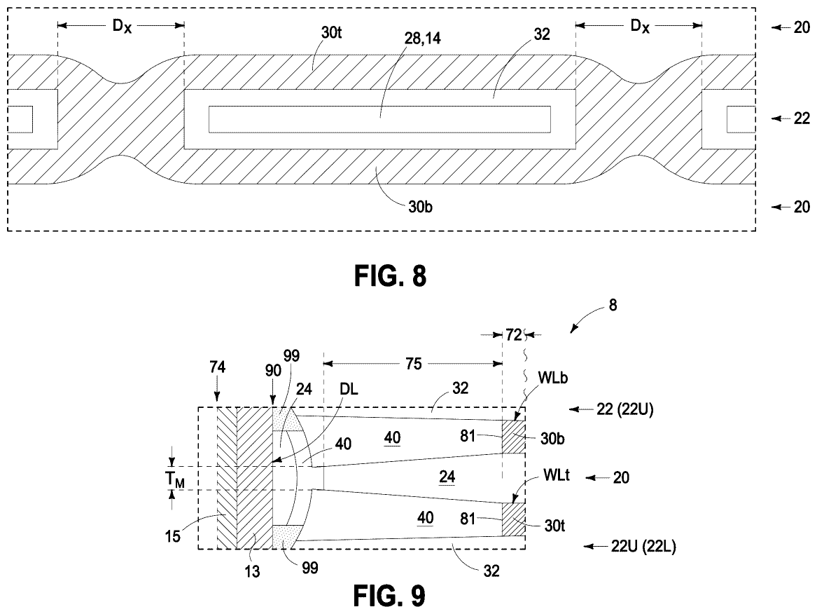

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-13.

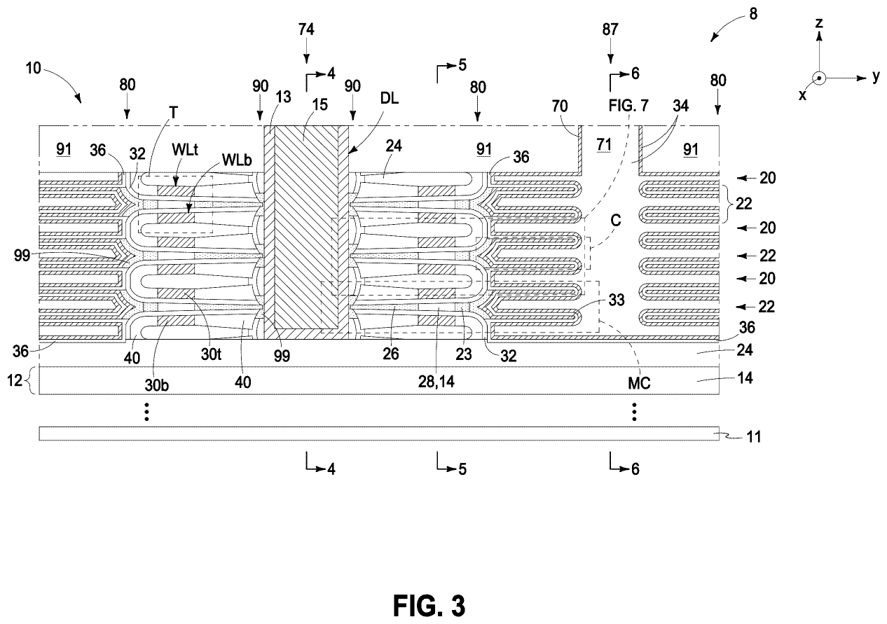

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+have the wordlines/access lines running horizontally and the digitlines/sense lines running vertically.

Referring to FIGS. 3-9, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-9—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

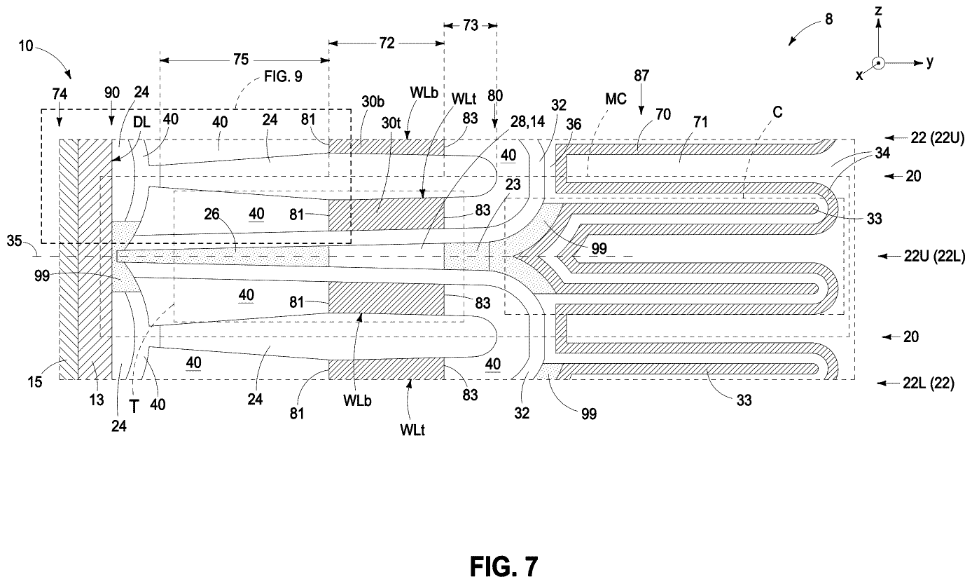

Example memory circuitry (e.g., that of or comprising construction 8) comprises vertically-alternating insulative tiers 20 and memory-cell tiers 22* (e.g., along example direction z; an * being used as a suffix to be inclusive of all such same-numerically-designated structures or portions thereof that may or may not have other suffixes). An example insulating material/hardmask 91 (e.g., silicon dioxide) is above tiers 20 and 22*. Memory cells MC are in memory-cell tiers 22* and individually comprise a horizontal transistor T and a capacitor C. Horizontal transistor T has a gate 30*, a capacitor side 80, and a digitline side 90. A horizontally-elongated trench 74 is shown in construction 8 on digitline side 90 (e.g., a digitline trench). A horizontally-elongated trench 87 is shown in construction 8 on capacitor side 80 (e.g., a capacitor trench). Capacitor C is electrically coupled (e.g., directly electrically coupled) with horizontal transistor T on capacitor side 80. A digitline DL is electrically coupled (e.g., directly electrically coupled) with horizontal transistor T on digitline side 90. Immediately-vertically-adjacent of the memory-cell tiers comprise an upper memory-cell tier (e.g., 22U in FIG. 7) and a lower memory-cell tier (e.g., 22L in FIG. 7) (there being no other such noun [tier] between those that are immediately-adjacent one another). Each memory-cell tier 22* may of course be considered as either an upper or a lower memory-cell tier depending on whether “immediately-vertically-adjacent” is referring to above or below with respect to the tiers 22* at issue.

Example horizontal transistor T comprises a first source/drain region 23 (e.g., conductively-doped silicon), a second source/drain region 26 (e.g., conductively-doped silicon), and a channel region 28 (e.g., lightly-doped or undoped silicon 14) horizontally between the first and second source/drain regions. The y-direction lengths of regions 23, 26, and 28 are diagrammatic in the figures. Such may be of equal or different lengths relative one another than is shown. Regions 23 and 26 of different immediately-horizontally-adjacent memory cells MC running into and out of the plane of the page upon which FIG. 3 lies in a common memory-cell tier 22* (along a horizontal x-direction) may be isolated relative one another by insulative material (not shown). A horizontal axis 35 (FIG. 7) extends from capacitor side 80 to digitline side 90 through channel region 28 and source/drain regions 23, 26 along a horizontal y-direction (that is perpendicular the x-direction). In some embodiments, regions 23, 26, and/or 28 taper towards digitline DL.

Example gate 30* (e.g., conductive metal material) of transistor T is gate-all-around channel region 28 having a gate insulator 32 (e.g., dielectric or ferroelectric) between at least channel region 28 and gate 30*. Gate 30* comprises part of a one of a plurality of horizontal conductive access lines WL* that individually directly electrically couple together multiple gates 30* of different ones of horizontal transistors T that are in the same memory-cell tier 22*. An example insulator material 40 (e.g., silicon nitride) is laterally proximate lateral sides/edges of gates 30* (e.g., digitline-side edge 81 and capacitor-side edge 83). In one embodiment and as shown, gate 30* comprises a top gate 30t that is part of a top conductive access line WLt and comprises a bottom gate 30b that is part of a bottom conductive access line WLb. The y-direction lengths of conductive access lines WLt and WLb are diagrammatic. Such may be of equal or different lengths relative one another than is shown and/or may or may not be centered in the y direction (with channel region 28) between the capacitors and transistors.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material 99 (e.g., conductively-doped epitaxial silicon) may be between storage-node electrode 33 and first source/drain region 23 (e.g., and such may be considered as a part of either or both).

Digitlines DL (e.g., comprising conductive materials 13 and 15) extend through vertically-alternating tiers 20 and 22*. Conductively-doped semiconductive material 99 may be between/proximate digitline DL and second source/drain region 26. Digitlines DL of different immediately-horizontally-adjacent memory cells MC running into and out of the plane of the page upon which FIG. 3 lies (in the x-direction) may be isolated relative one another by insulative material 62 (e.g., silicon dioxide and/or silicon nitride). Individual second source/drain regions 26 of individual transistors T that are in different memory-cell tiers 22* are electrically coupled (e.g., directly electrically coupled) to individual digitlines DL. Capacitor C and horizontal transistor T may be considered as being horizontally spaced relative one another along horizontal axis 35 (FIG. 7) along the y-direction.

Insulative tiers 20 comprise insulative material 24 that is vertically between immediately-vertically-adjacent memory-cell tiers 22*. In one embodiment, insulative material 24 (FIG. 7) comprises a first portion 72 that is between gates 30* of immediately-vertically-adjacent memory cells MC, a second portion 73 that is laterally beyond capacitor side 80 of gates 30* of immediately-vertically-adjacent memory cells MC, and a third portion 75 that is laterally beyond digitline side 90 of gates 30* of immediately-vertically-adjacent memory cells MC. First and second portions 72, 73 taper towards capacitor C (in the same or different average degree[s] relative one another, regardless of whether such taper is continuous as long as average taper of each portion is overall towards capacitor C, and regardless of whether such taper[s] is/are constant [constant and same being shown]).

One of (A), (B), and (C) exists, where:
(A): third portion 75 tapers towards digitline DL;
(B): third portion 75 tapers towards capacitor C with less average taper than those of each of first and second portions 72, 73; and
(C): third portion 75 has horizontal top and bottom surfaces 76, 77, respectively (FIGS. 12 and 13).

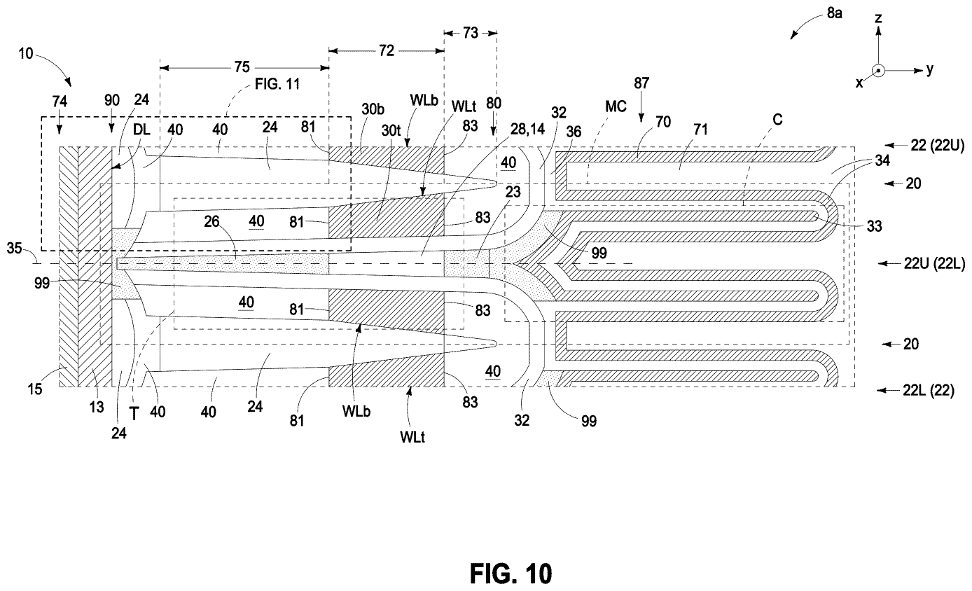

FIGS. 3 and 7 show the (A). FIG. 10/11 and 12/13 show constructions 8a and 8b, respectively, having the (B) and the (C), respectively. Like numerals from the above-described embodiments have been used where appropriate, with some construction differences being indicated with the suffix “a” or “b”, respectively, or with different numerals. Any other attribute(s) or aspect(s) as shown and/or described herein with respect to other embodiments may be used.

In one embodiment, insulative tiers 20 in the construction (e.g., 8) includes a portion of insulative material 24 that is laterally beyond digitline-side edge 81 of gates 30* of immediately-vertically-adjacent memory cells MC (e.g., 75) (regardless of taper or non-taper attributes of other portions of insulative material 24), with such portion (e.g., 75) tapering towards digitline DL. In some such embodiments, horizontal transistor T comprises a source/drain region 26 on digitline side 90 of individual gates 30* that tapers towards digitline DL, comprises a channel region 28, 14 that tapers towards digitline DL, and/or comprises a source/drain region 23 on capacitor side 80 of individual gates 30* that tapers towards digitline DL. Any other attribute(s) or aspect(s) as shown and/or described herein with respect to other embodiments may be used.

Any other attribute(s) or aspect(s) as shown and/or described herein with respect to other embodiments may be used in the embodiments shown and described with reference to the above embodiments.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

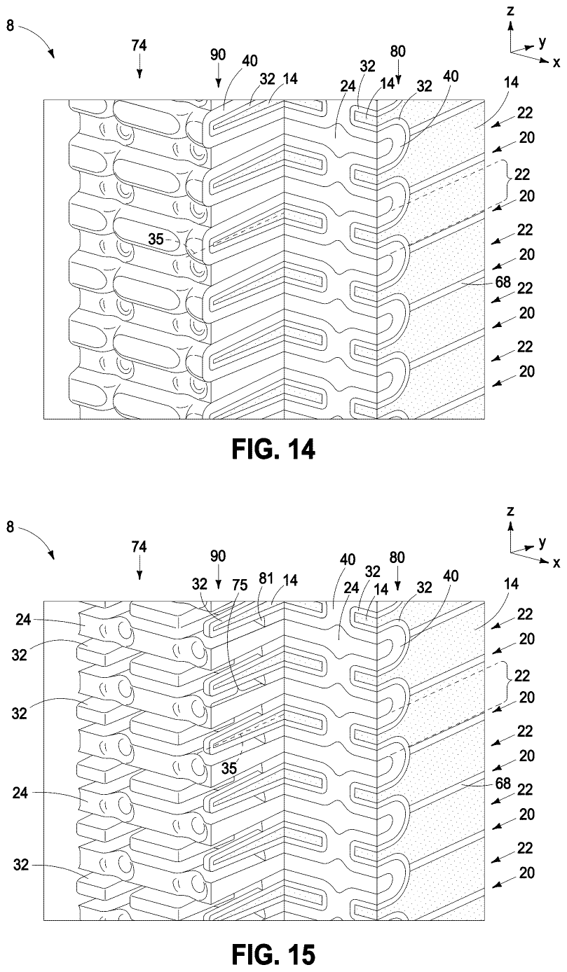

FIGS. 14-21 by way of example sequentially show predecessor constructions in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the invention as described above with respect to FIGS. 3-13.

Referring to FIG. 14, vertically-alternating insulative tiers 20 and memory-cell tiers 22* have been formed. Memory cells (not-yet-formed) of memory-cell tiers 22* individually comprise a horizontal transistor (not-yet-completely-formed) and a capacitor (not-yet-formed) in a finished memory-circuitry construction. The horizontal transistor in the finished circuitry construction has a gate 30* (not-yet-formed), a capacitor side 80, and a digitline side 90. Example memory-cell tiers 22* comprise doped or undoped semiconductor material 14 which may in its intrinsic composition be used as a channel material/region 14, 28. Such is shown as being lightly stippled for clarity in FIGS. 14-20, although corresponding channel material/region 14, 28 is not shown as being stippled in FIGS. 3-12 and 21.

Insulative tiers 20 comprise insulative material 24 that is vertically between immediately-vertically-adjacent memory-cell tiers 22*. Insulative material 24 in the finished-circuitry construction comprises a first portion 72 (not shown or designated in FIG. 14+) that is between gates 30* of immediately-vertically-adjacent memory cells MC, a second portion 73 that is laterally beyond capacitor-side edge 83 of gates 30* (edges 83 not-yet-shown) of immediately-vertically-adjacent memory cells MC, and a third portion 75 that is laterally beyond digitline-side edge 81 of gates 30* (edges 81 not-yet-shown) of immediately-vertically-adjacent memory cells MC. First and second portions 72, 73 taper towards capacitor side 80 of horizontal transistor T in the finished-circuitry construction (at least). Immediately-vertically-adjacent memory-cell tiers 22* may be considered as comprising an upper memory-cell tier 22* and a lower memory-cell tier 22* analogous to tiers 22U and 22L as described above although not-so-designated in FIGS. 14-21. Insulator material 40 and gate insulator 32 may have been provided as shown. The horizontal transistor being formed may be considered as comprising a horizontal axis 35 extending from capacitor side 80 to digitline side 90 along a horizontal y-direction.

As one example, all of insulative material 24 is shown initially tapering towards capacitor side 80 (away from digitline side 90). Such may result from semiconductor material 14 being formed to taper towards digitline side 90. This may result from processing relative to an initial vertical stack comprising alternating layers of semiconductor material 14 (of thickness as shown in the far-right portion of FIG. 14) and a much thinner material 68 that can be etched at least somewhat selectively relative to material 14 (e.g., a silicon-germanium alloy). Etching of such thinner material 68 from digitline side 90 in a digitline trench 74 may also etch some of material 14 and, if so, to a greater degree proximate digitline trench 74 than distal therefrom. Alternately or additionally, a subsequent etch of material 14 from within gaps formed by the removal of thinner material 68 exposes material 14 more proximate digitline trench 74 to more etching action than material 14 that is distal therefrom. Regardless, the depicted taper of material 14 towards digitline trench 74 (digitline side 90) will result. Subsequent depositions of materials 32, 40 and 24 will result in the FIG. 14—depicted profile (e.g., with material 24 tapering towards capacitor side 80).

Referring to FIG. 15, and in one embodiment, insulator material 40 has been laterally recessed back (e.g., by etching using H₃PO₄ if silicon nitride) to have a digitline-side edge 81 that is laterally-coincident with digitline-side edge 81 of individual gates 30* in the finished-circuitry construction.

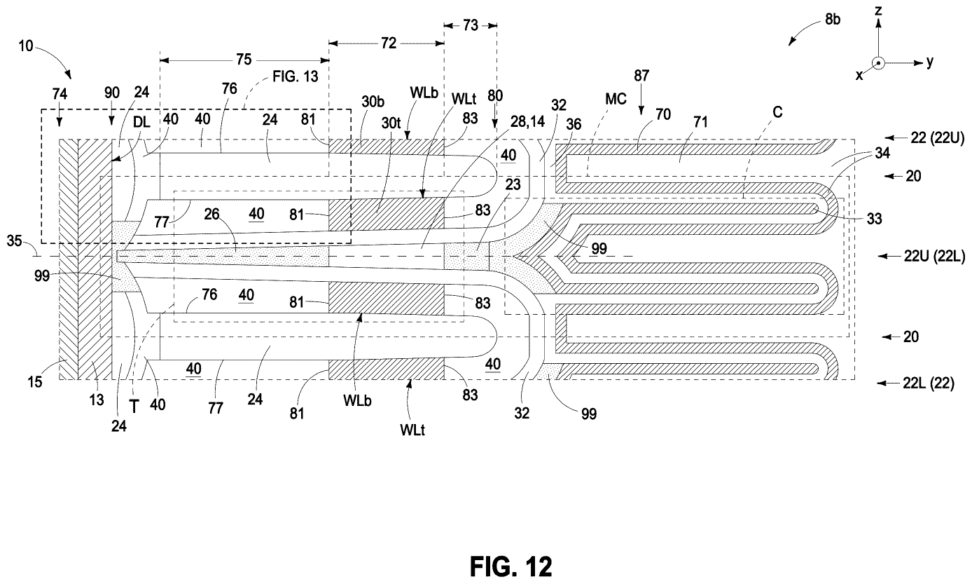

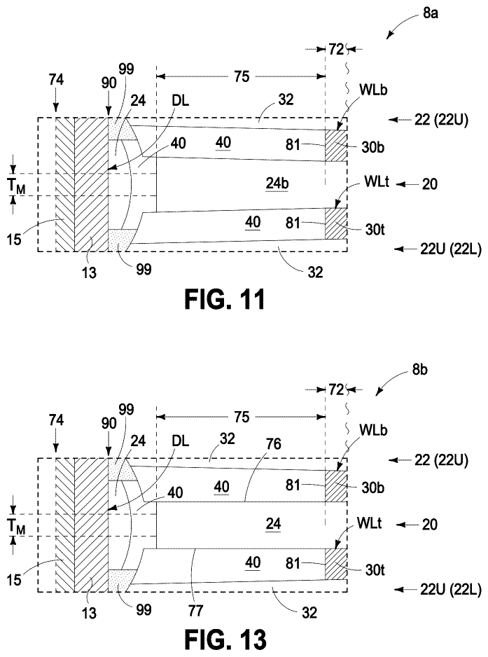

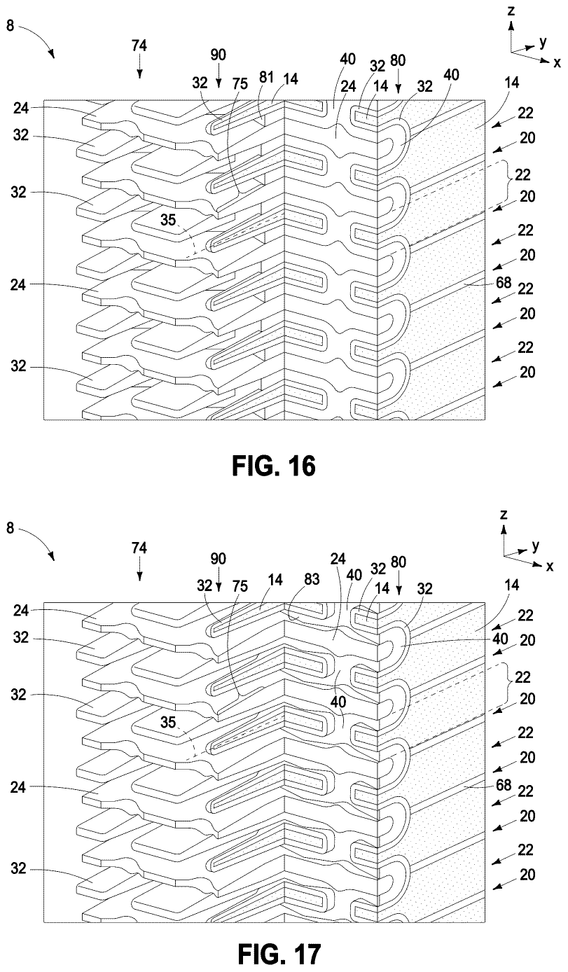

FIG. 16 follows the processing shown by FIG. 15. Some of third portion 75 of insulative material 24 is removed (e.g., by etching) such that, after the removing, one of (A), (B), and (C) exists, where:
(A): third portion 75 tapers towards digitline DL (FIGS. 3, 7, and 16);
(B): third portion 75 tapers towards capacitor C with less average taper than those of each of first and second portions 72, 73 (FIGS. 10 and 11); and
(C): third portion 75 has horizontal top and bottom surfaces (e.g., 76, 77, respectively, in FIGS. 12 and 13).

For example, where insulative material 24 is silicon dioxide, etching chemistry comprising HF or another fluorine-containing chemistry may be used depending on which of (A), (B), or (C) is desired. The artisan will appreciate that etching chemistry, etching conditions, and time that the etch is allowed to proceed can be tailored to achieve one of (A), (B), or (C) and depending on composition of insulative material 24. FIG. 16 and FIGS. 17-21 show processing relative to (A) although/and analogous processing could be conducted relative to (B) or (C).

Referring to FIG. 17, and in one embodiment, insulator material 40 has been laterally recessed back (e.g., by etching using H₃PO₄ if silicon nitride) to have a capacitor-side edge 83 that is laterally-coincident with what will be capacitor-side edge 83 of individual gates 30* in the finished-circuitry construction.

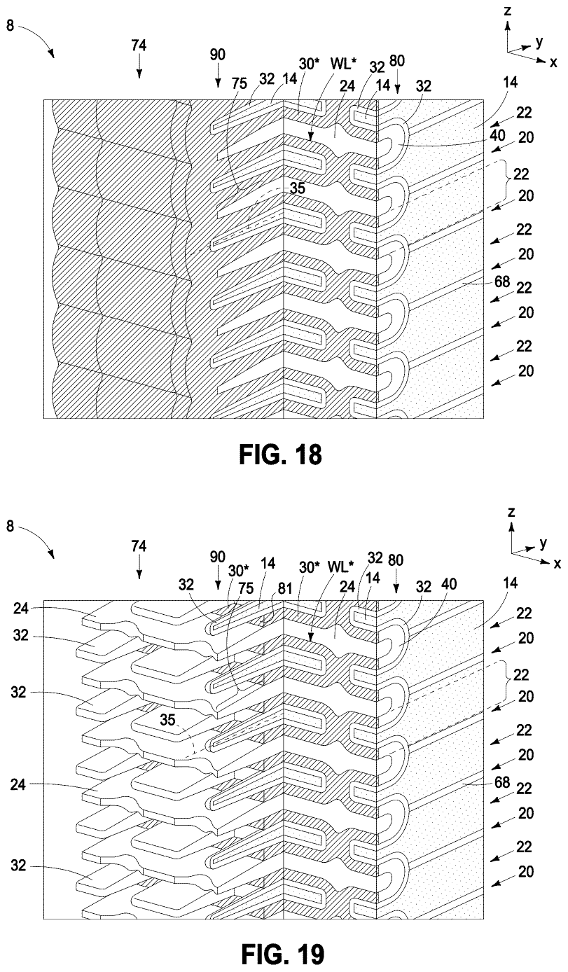

FIG. 18 shows forming of the conductive material of gates 30*/access lines WL* (not-yet-completed) in the void-space that was left from the removal of portions of materials 40 and 24.

FIG. 19 shows removal of some of such conductive material to form the final shape of gates 30*/access lines WL*.

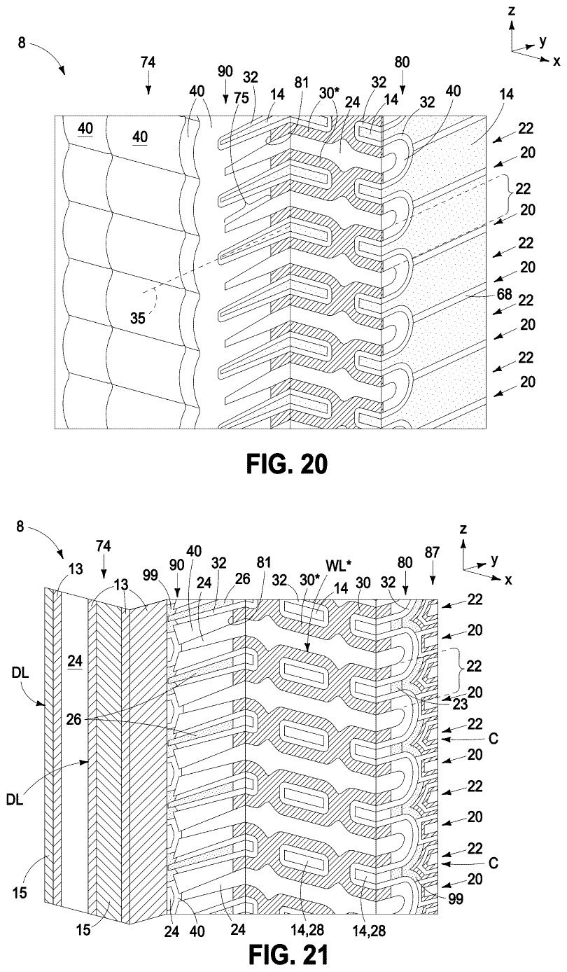

FIG. 20 shows the forming of more insulator material 40 in digitline trenches 74.

Referring to FIG. 21, and in some embodiments, several processing steps from FIG. 20 have occurred. Some insulator material 40 has been removed from memory cell tiers 22* from/through digitline trench 74. Gate insulator 32 has been removed to expose semiconductor material 14 and then such exposed material 14 has been conductively doped to form source/drain region 26 (e.g., by gas-phase diffusion). Conductively-doped epitaxial silicon 99 has then been grown from exposed semiconductor material 14 (source/drain region 26 thereof). Thereafter, insulator material 40 and insulative material 24 were formed in digitline trench 74. Trenches in which digitlines DL would be formed were then formed laterally into such insulator material 40 and insulative material 24. Such has also etched-back materials 99, 24, and 40 at the capacitor sides of such trenches as shown. A digitline DL was then formed in individual of such trenches and that are individually electrically coupled with horizontal transistor T on digitline side 90. A capacitor C was then formed electrically coupled with horizontal transistor T on capacitor side 80. Capacitor C, for example, can be formed be first forming capacitor trench 87 on capacitor side 80 to expose semiconductor material 14 of the horizontal transistor T's being formed. Such may be conductively doped to form source/drain region 23 (e.g., by gas-phase diffusion) followed by formation of capacitors C. Again, channel region/semiconductor material 14, 28 is shown without stippling in FIG. 21 for clarity and consistency with FIGS. 1-8. Conductively-doped semiconductive material 99 may be formed prior to forming components of capacitor C. Capacitors C and digitlines DL may be formed in any order relative one another.

Some embodiments of the invention were motivated towards reducing existence or volume of void spaces in the conductive material of access lines WL* that can develop between the gate insulator of immediately-horizontally-adjacent horizontal transistors in the x-direction. Embodiments herein may reduce the existence or volume of such void spaces.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of the vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming vertically-alternating insulative tiers and memory-cell tiers. Memory cells of the memory-cell tiers individually comprise a horizontal transistor and a capacitor in a finished-circuitry construction. The horizontal transistor in the finished-circuitry construction has a gate, a capacitor side, and a digitline side. The insulative tiers comprise insulative material that is vertically between immediately-vertically-adjacent of the memory-cell tiers. The insulative material in the finished-circuitry construction comprises a first portion that is between the gates of the immediately-vertically-adjacent memory cells, a second portion that is laterally beyond a capacitor-side edge of the gates of the immediately-vertically-adjacent memory cells, and a third portion that is laterally beyond a digitline-side edge of the gates of the immediately-vertically-adjacent memory cells. The first and second portions taper towards the capacitor side of the horizontal transistor in the finished-circuitry construction. Some of the third portion of the insulative material is removed. After the removing, one of (A), (B), and (C) exists, where:
(A): the third portion tapering towards the digitline side;
(B): the third portion tapering towards the capacitor with less average taper than those of each of the first and second portions; and
(C): the third portion having horizontal top and bottom surfaces.

In some embodiments, memory circuitry comprises vertically-alternating insulative tiers and memory-cell tiers. Memory cells in the memory-cell tiers individually comprise a horizontal transistor have a gate, a capacitor side, and a digitline side. A capacitor is electrically coupled with the horizontal transistor on the capacitor side. A digitline is electrically coupled with the horizontal transistor on the digitline side. The insulative tiers comprise insulative material that is vertically between immediately-vertically-adjacent of the memory-cell tiers. The insulative material comprises a first portion that is between the gates of the immediately-vertically-adjacent memory cells, a second portion that is laterally beyond a capacitor-side edge of the gates of the immediately-vertically-adjacent memory cells, and a third portion that is laterally beyond a digitline-side edge of the gates of the immediately-vertically-adjacent memory cells. The first and second portions taper towards the capacitor. One of (A), (B), and (C) exists, where:
(A): the third portion tapering towards the digitline side;
(B): the third portion tapering towards the capacitor with less average taper than those of each of the first and second portions; and
(C): the third portion having horizontal top and bottom surfaces.

In some embodiments, memory circuitry comprises vertically-alternating insulative tiers and memory-cell tiers. Memory cells in the memory-cell tiers individually comprise a horizontal transistor have a gate, a capacitor side, and a digitline side. A capacitor is electrically coupled with the horizontal transistor on the capacitor side. A digitline is electrically coupled with the horizontal transistor on the digitline side. The insulative tiers comprise insulative material that is vertically between immediately-vertically-adjacent of the memory-cell tiers. A portion of the insulative material is laterally beyond a digitline-side edge of the gates of the immediately-vertically-adjacent memory cells. The portion tapers towards the digitline.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating insulative tiers and memory-cell tiers, memory cells of the memory-cell tiers individually comprising a horizontal transistor and a capacitor in a finished-circuitry construction, the horizontal transistor in the finished-circuitry construction having a gate, a capacitor side, and a digitline side;
the insulative tiers comprising insulative material that is vertically between immediately-vertically-adjacent of the memory-cell tiers; the insulative material in the finished-circuitry construction comprising a first portion that is between the gates of the immediately-vertically-adjacent memory cells, a second portion that is laterally beyond a capacitor-side edge of the gates of the immediately-vertically-adjacent memory cells, and a third portion that is laterally beyond a digitline-side edge of the gates of the immediately-vertically-adjacent memory cells; the first and second portions tapering towards the capacitor side of the horizontal transistor in the finished-circuitry construction; and
removing some of the third portion of the insulative material; after the removing, one of (A), (B), and (C), where:
(A): the third portion tapering towards the digitline side;
(B): the third portion tapering towards the capacitor with less average taper than those of each of the first and second portions; and
(C): the third portion having horizontal top and bottom surfaces.

2. The method of claim 1 comprising, after the removing, forming the gates.

3. The method of claim 1 comprising, after the removing, forming a digitline electrically coupled with the horizontal transistor on the digitline side.

4. The method of claim 1 comprising, after the removing, sequentially comprising:
forming the gates; and
forming a digitline electrically coupled with the horizontal transistor on the digitline side.

5. The method of claim 1 comprising, after the removing, forming the gates and forming the capacitor electrically coupled with the horizontal transistor on the capacitor side.

6. The method of claim 1 comprising:
before the removing, laterally recessing insulator material that is in individual of the memory-cell tiers to have a digitline-side edge that is laterally-coincident with a digitline-side edge of individual of the gates in the finished-circuitry construction;
after the removing, laterally recessing the insulator material that is in the individual memory-cell tiers to have a capacitor-side edge that is laterally-coincident with a capacitor-side edge of the individual gates in the finished-circuitry construction; and
after both of the laterally recessings, forming the gates.

7. The method of claim 1 comprising the (A).

8. The method of claim 1 comprising the (B).

9. The method of claim 1 comprising the (C).

10. The method of claim 1 wherein the gate of the horizontal transistor comprises a top gate and a bottom gate having channel material vertically there-between in the finished-circuitry construction.

11. Memory circuitry comprising:
vertically-alternating insulative tiers and memory-cell tiers;
memory cells in the memory-cell tiers that individually comprise a horizontal transistor having a gate, a capacitor side, and a digitline side; a capacitor electrically coupled with the horizontal transistor on the capacitor side, a digitline electrically coupled with the horizontal transistor on the digitline side; and
the insulative tiers comprising insulative material that is vertically between immediately-vertically-adjacent of the memory-cell tiers; the insulative material comprising a first portion that is between the gates of the immediately-vertically-adjacent memory cells, a second portion that is laterally beyond a capacitor-side edge of the gates of the immediately-vertically-adjacent memory cells, and a third portion that is laterally beyond a digitline-side edge of the gates of the immediately-vertically-adjacent memory cells; the first and second portions tapering towards the capacitor, one of (A), (B), and (C), where:
(A): the third portion tapering towards the digitline;
(B): the third portion tapering towards the capacitor with less average taper than those of each of the first and second portions; and
(C): the third portion having horizontal top and bottom surfaces.

12. The memory circuitry of claim 11 comprising the (A).

13. The memory circuitry of claim 11 comprising the (B).

14. The memory circuitry of claim 11 comprising the (C).

15. The memory circuitry of claim 11 wherein the horizontal transistor comprises a channel region that tapers towards the digitline.

16. The memory circuitry of claim 11 wherein the gate of the horizontal transistor comprises a top gate and a bottom gate having channel material vertically there-between.

17. The memory circuitry of claim 16 wherein the horizontal transistor comprises a channel region that is vertically between the top and bottom gates, the channel region tapering towards the digitline.

18. Memory circuitry comprising:
vertically-alternating insulative tiers and memory-cell tiers;
memory cells in the memory-cell tiers that individually comprise a horizontal transistor having a gate, a capacitor side, and a digitline side; a capacitor electrically coupled with the horizontal transistor on the capacitor side, a digitline electrically coupled with the horizontal transistor on the digitline side; and
the insulative tiers comprising insulative material that is vertically between immediately-vertically-adjacent of the memory-cell tiers, a portion of the insulative material being laterally beyond a digitline-side edge of the gates of the immediately-vertically-adjacent memory cells, the portion tapering towards the digitline.

19. The memory circuitry of claim 18 wherein the horizontal transistor comprises a source/drain region on the digitline side of individual of the gates and that tapers towards the digitline.

20. The memory circuitry of claim 19 wherein the horizontal transistor comprises a channel region that tapers towards the digitline.

21. The memory circuitry of claim 20 wherein the horizontal transistor comprises a source/drain region on the capacitor side of the individual gates and that tapers towards the digitline.
